(19) United States
(12) Patent Application Publication
(10) Pub. No.: US 2008/0179715 A1
(43) Pub. Date: Jul. 31, 2008

(54) Shallow trench isolation using atomic layer deposition during fabrication of a semiconductor device

(75) Inventor: Brian J. Coppa, Boise, ID (US)

Correspondence Address: MICRON TECHNOLOGY, INC., 8000 FEDERAL WAY, MAIL STOP 525, BOISE, ID, 83707-0006, US

(73) Assignee: Micron Technology, Inc.

(21) Appl. No.: 11/699,876

(22) Filed: Jan. 30, 2007

(51) Int. Cl. H01L 23/58; H01L 21/76

(52) U.S. Cl. 257/647; 438/435; 257/E23.001; 257/E21.54

(57) ABSTRACT

A method for providing an isolation material, for example trench isolation for a semiconductor device, comprises forming a first dielectric such as silicon dioxide using an atomic layer deposition (ALD) process within a trench, partially etching the first dielectric, then forming a second dielectric such as a silicon dioxide using a high density plasma (HDP) deposition within the trench. The second dielectric provides desirable properties such as resistance to specific etches than the first dielectric, while the first dielectric fills high aspect ratio openings more easily than the second dielectric. Depositing the first dielectric results in a decreased trench aspect ratio which must be filled by the second dielectric.

### TECHNICAL FIELD

Various embodiments of the present disclosure relate to the field of semiconductor manufacture and, more particularly, to a method for filling a trench or other opening with a dielectric, which may be useful as shallow trench isolation (STI).

### BACKGROUND

Implementing electronic circuits involves connecting electrically isolated devices through specific electronic paths. In silicon integrated circuit fabrication it is necessary to isolate devices which are built into the same silicon matrix from one another. The devices are subsequently interconnected to create the desired circuit configuration. In the continuing trend toward higher device densities, parasitic interdevice currents become more problematic, thus isolation technology has become one of the most critical aspects of contemporary integrated circuit fabrication.

Over the last few decades a variety of successful isolation technologies have been developed to address the requirements of different integrated circuit types such as complimentary metal oxide semiconductor (CMOS), n-channel metal oxide semiconductor (NMOS), and bipolar devices. In general, the various isolation technologies exhibit different attributes with respect to such characteristics as minimum isolation spacing, surface planarity, process complexity and defect density generated during isolation processing. Moreover, it is common to trade off some of these characteristics when developing an isolation process for a particular integrated circuit application.

In metal-oxide-semiconductor (MOS) technology it is necessary to provide an isolation structure which prevents parasitic channel formation between adjacent devices, such devices being primarily NMOS or p-channel metal oxide semiconductor (PMOS) transistors, or CMOS circuits. The most widely used isolation technology for MOS circuits has been that of local oxidation of silicon (LOCOS) isolation. LOCOS isolation comprises the growth of a recessed or semirecessed oxide in non-active or field regions of the silicon substrate. This so-called field oxide is generally grown thick enough to decrease any parasitic capacitance occurring over these regions, but not so thick as to cause step coverage problems of subsequently formed materials. The success of LOCOS isolation technology is to a large extent attributed to its inherent simplicity in MOS process integration, cost effectiveness and adaptability.

In spite of its success, several limitations of LOCOS technology have driven the development of alternative isolation structures. A well-known limitation in LOCOS isolation is the unwanted growth of the oxide under the edge of the mask which defines the active regions of the substrate. This growth results in an oxide profile which appears as a “bird's beak” and reduces device density, since that portion of the oxide results in an increased distance between a subsequently formed transistor gate and a conductive region within the substrate. Another problem associated with the LOCOS process is the formation of nonplanar surface topography. For submicron devices, maintaining surface planarity becomes an important issue, often posing problems with subsequent material conformity and photolithography.

Trench isolation technology has been developed in part to overcome the limitations of LOCOS isolation for submicron devices. Trench isolation comprise the formation of a dielectric within a trench recess in the silicon substrate. Trench isolation is fabricated by first forming trenches in the silicon substrate, typically using an anisotropic etching process. The resulting trenches generally display a steep sidewall profile as compared with LOCOS oxidation. The trenches are subsequently filled with a dielectric such as chemical vapor deposited (CVD) silicon dioxide (SiO₂). The SiO₂ fill is then planarized using an etch back process so that the dielectric remains only in the trench, its top surface level with that of the silicon substrate. The etch back process may be performed by etching photoresist and the deposited silicon dioxide at the same rate. The top surface of the resist is highly planarized prior to etch back through first and second photoresist applications, and flowing the first resist prior to forming the second. Active regions where transistors and other devices fabricated are protected from the etch during formation of the trenches. The resulting trench isolation functions as an electrical insulator having an upper surface which is generally planar with the surface of the semiconductor wafer. The trenches may be formed to have a high aspect ratio (i.e. a depth to width ratio of about 4:1 or more) which may be necessary for device requirements. Shallow trench isolation (STI) is used primarily for isolating devices of the same type and is often considered an alternative to LOCOS isolation. Shallow trench isolation has the advantages of eliminating the bird's beak of LOCOS and providing a high degree of surface planarity.

One trench isolation process comprises only partially filling the trench using high density plasma (HDP) oxide, etching back the HDP oxide using hydrofluoric acid (HF), then completing the fill using another HDP oxide fill. This deposit-etch-deposit process may be performed numerous times with a small thickness increase with each iteration until the trench is filled. During formation of the initial HDP oxide, the material at the top thickens more quickly than the rest of the material. If only one thick HDP oxide application is used to fill the trench, the HDP oxide may pinch off at the top of the opening, thereby leaving a void in the center of the isolation, a defect known as “keyholing.” By exposing the initial HDP oxide to an HF etch, the opening is expanded to allow the HDP oxide to provide a more complete fill of the trench.

As-deposited HDP oxide demonstrates good dry and wet etch resistance during subsequent wafer processing, for example during a HF-based clean to remove residual SiO₂ after chemical mechanical polishing (CMP) in flash memory device fabrication. While other oxides such as atomic layer deposited (ALD) oxide may have a decreased propensity to form voids, HDP oxide is used because of its superior etch resistance and sufficient gate and high voltage periphery device isolation properties. Conformal, less dense oxides such as CVD ozone TEOS (O₃-TEOS) or ALD SiO₂ are preferentially etched at the seam when exposed to HF-based chemistries and thus cannot be used as the sole isolation.

HDP oxide is, however, subject to typical drawbacks such as keyholing and void formation in the trench. These voids compromise device isolation as well as the overall structural integrity, which may lead to short circuits between gates. With relatively larger trench openings, the negative aspects of HDP oxide may be reduced. However, with future device designs and diminishing trench widths, the use of HDP oxide may become more problematic.

Shallow trench isolation processes which reduce defects, allow for scalability to decreasing device sizes, and provide effective device isolation are desirable.

### BRIEF DESCRIPTION OF THE DRAWINGS

FIGS. 1-12 are cross sections depicting in-process structures formed using an embodiment of the invention to form shallow trench isolation;

FIG. 13 is a simplified schematic representation of an ALD process reaction chamber and associated apparatus which can be used to deposit a conformal material according to embodiments of the invention.

FIG. 14 is an isometric depiction of various components which may be manufactured using devices formed with an embodiment of the present invention; and

FIG. 15 is a block diagram of one particular use of an embodiment of the invention to form part of a memory device having a storage transistor array.

It should be emphasized that the drawings herein may not be to exact scale and are schematic representations. The drawings are not intended to portray the specific parameters, materials, particular uses, or the structural details of the various described embodiments of the invention, which may be determined by one of skill in the art by examination of the information herein.

### DETAILED DESCRIPTION

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with materials including dielectrics and conductors, and features such as transistors, formed thereover, depending on the particular stage of processing. In addition, the semiconductor need not be silicon-based, but may be based on silicon-germanium, silicon-on-insulator, silicon-on-sapphire, germanium, or gallium arsenide, among others. Further, in the discussion and claims herein, the term “on” used with respect to two materials, one “on” the other, means at least some contact between the materials, while “over” means the materials are in close proximity, but possibly with one or more additional intervening materials such that contact is possible but not required. Neither “on” nor “over” implies any directionality as used herein. The term “conformal” describes a coating material in which angles of the underlying material are generally preserved by the conformal material on both its top and bottom surfaces. The term “about” indicates that the value listed may be somewhat altered, as long as the alteration does not result in nonconformance of the process or structure to the described embodiment. A “spacer” indicates a material, typically dielectric, formed as a conformal material over uneven topography then anisotropically etched to remove horizontally oriented portions of the material while leaving vertically oriented portions of the material.

A first embodiment of an inventive method for forming a semiconductor device comprising trench isolation such as shallow trench isolation (STI) is depicted in FIGS. 1-12. FIG. 1 depicts a portion of a semiconductor wafer 10, a high quality tunnel silicon dioxide 12 (or gate oxide, depending on the device being fabricated), and a sacrificial material 14 such as silicon nitride formed on the tunnel oxide. An alternate process may use a pad oxide instead of the tunnel oxide 12, with the tunnel oxide being formed at a later fabrication stage. FIG. 1 further depicts a patterned photoresist (resist) 16 formed over material 14. Resist 16 comprises spaces 18, and will be used to define isolation trenches. The structure of FIG. 1, which may comprise other features not depicted and not immediately germane to the present invention, may be formed by one of ordinary skill in the art.

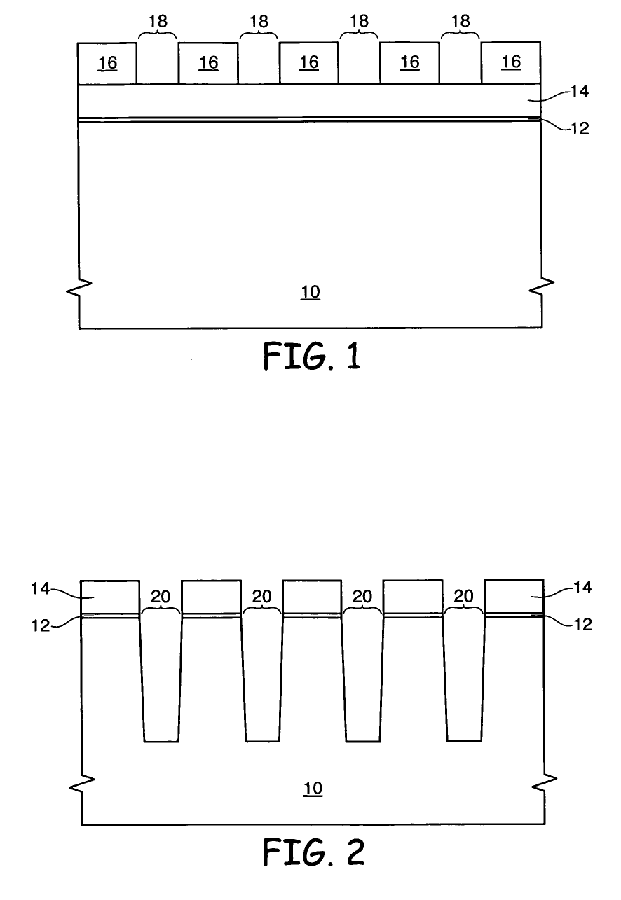

After forming the FIG. 1 structure, an anisotropic etch is performed to etch sacrificial material 14, tunnel oxide 12, and wafer 10. Subsequently, resist 16 is removed to result in the structure of FIG. 2, which depicts isolation trenches 20 formed within the semiconductor wafer 10. In a typical embodiment with current processing techniques and for illustration purposes only, the trench portion within the semiconductor wafer (i.e. not including the tunnel oxide 12 and the sacrificial material 14) may be about 500 Å (±100 Å) or less wide at the top and may have an aspect ratio of between about 5:1 (i.e. a depth about five time the width) to about 8:1. Thus the trench may be between about 2,500 Å and about 4,000 Å deep to achieve an aspect ratio of between 5:1 and 8:1 for a 500 Å wide opening.

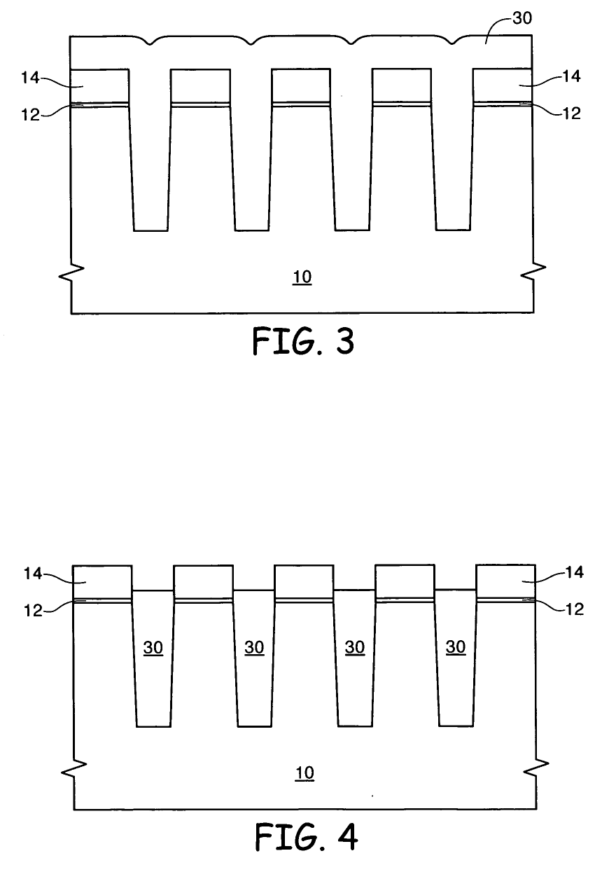

After forming the FIG. 2 structure, a first isolation material 30 is formed within the trench as depicted in FIG. 3. The first isolation material is selected to provide a complete fill of the trench with minimal voiding. In this embodiment, an atomic layer deposited (ALD) silicon dioxide material is formed to a thickness which is at least above a level of the tunnel oxide 12, and in this embodiment the trench is completely filled as depicted in FIG. 3. In one specific ALD process for a trench 4,000 Å deep and 500 Å wide, the ALD oxide is targeted to a thickness of 600 Å which, because the target thickness is greater than half the width of the trench, will fill the trench as illustrated in FIG. 3 such that the surface of the ALD oxide at a location above the trench is higher than the upper surface of the nitride 14.

ALD oxide is specifically selected due to its ability to fill trenches having very high aspect ratios, or other openings in a semiconductor wafer substrate assembly. Aspect ratios for future generation devices such as flash memory devices may require aspect ratios of 8:1 and higher. When coupled with openings having a width of 50 nm or less it becomes increasingly difficult to form sufficient isolation without voiding, and with openings 35 nm wide or less it becomes impossible to form void-free openings with HDP and most other oxide dielectrics. HDP oxide is inadequate for filling deep trenches having small openings, for example 500 Å widths or less and aspect ratios greater than about 5:1, because of its problems with voiding and potential gate isolation failure.

To form the ALD silicon dioxide material 30, the wafer substrate assembly may be exposed to a first mixture (a precursor) comprising a silicon-based compound such as a silicon-halide having at least two silicon atoms, for example hexachlorodisilane (HCD) and to either a heterocyclic aromatic organic compound or to a Lewis base such as pyridine (C₅H₅N) which functions as a catalyst. During ALD oxide formation, the precursor and catalyst are flowed into the chamber at a sufficient rate to maintain the chamber at a pressure of between about 100 millitorr (mtorr) and 400 torr, more specifically between about 1 torr and 20 torr, for example at about 7 torr. During a flow of the gasses, the chamber is maintained at a temperature of between about 10° C. and about 90° C., and more preferably to between about 65° C. and about 80° C. Exposing the surface to the HCD precursor provides silicon and prepares the surface to accept oxygen. While HCD is referred to as a “precursor,” it reacts with the exposed surface by supplying silicon. HCD and pyridine may be introduced into the chamber at about the same flow rates (a ratio of about 1:1), but the actual flows may vary by up to ±50% due to a large range of growth conditions.

After exposure, the deposition chamber is purged, for example using nitrogen as a purge gas, and the exposed surface is subjected to a second mixture (a reactant) comprising a compound containing oxygen and hydrogen, for example water vapor and to either a heterocyclic aromatic organic compound or to a Lewis base, such as pyridine, which functions as a catalyst. In this embodiment, water vapor and pyridine are introduced at a sufficient rate to maintain the chamber at a pressure of between 100 mtorr and 400 torr, more specifically between 1 torr and 20 torr, for example at about 7 torr. As with the introduction of the precursor, the chamber is maintained to a temperature of between about 65° C. and about 80° C., for example about 75° C. The flow ratio of water and pyridine may be about 1:1 with a variation of up to about ±50%. The water vapor provides oxygen which reacts with the exposed silicon provided by the HCD precursor.

To form a material of sufficient thickness, the process of introducing the precursor then introducing the reactant with a purge between each exposure must be performed for several iterations. The precursor is introduced into the chamber for a duration of between about 2 seconds to about 60 seconds, the chamber is purged, then the reactant is introduced into the chamber for a duration of between about 2 seconds and about 60 seconds, and the chamber is again purged. Each cycle adds about 3 Å to the thickness of the ALD, thus to form a material 1,200 Å thick, the process is repeated about 400 times.

The following mechanism for ALD SiO₂ formation has been proposed in the literature. By exposing the functionalized substrate surface to the precursor, the aromatic organic compound generates hydrogen bonding with the silicon hydroxide on the substrate surface, thereby resulting in a weakening of the SiO—H bond. This may increase the nucleophilicity of the oxygen atom for reaction with the electron deficient silicon in the HCD to result in a silicon dichloride molecule on the surface of the substrate. Upon introduction of the reactant, the aromatic organic compound generates hydrogen bonding with the water causing the oxygen atom in the water molecule to become more nucleophilic for reaction with the electron deficient silicon dichloride molecule. This initiates a weakening of the Si—Cl bond causing a titration of the chlorine ion(s) by an OH ion, resulting in a monolayer of silicon dioxide on the substrate surface. In an alternate explanation of the chemical mechanism, the introduction of the reactant causes the direct interaction of the nitrogen ion of the aromatic organic compound with the electron deficient surface silicon atoms, weakening the Si—Cl bond, resulting in a titration of the chlorine ion by the hydroxyl group. It will be appreciated that the present invention is not bound or limited by the theorized reaction.

The ALD SiO₂ may also be grown using a silicon precursor and ozone as separate pulses into a reaction chamber. This process may be performed at a temperature of about 400° C. or greater. HCD is a suitable silicon precursor for this ALD process, while inert gases such as argon or nitrogen may be used as purge gases. The process logistics are analogous to those described herein for the pyridine process.

Regardless of the actual reaction mechanism or process used for ALD SiO₂ formation, atoms provided by the reactant bond with free binding sites on the surface of the wafer to provide a silicon dioxide material which is one molecule thick. Once all the binding locations are full, the SiO₂ surface is considered saturated. Thus several iterations of exposure of the semiconductor wafer substrate assembly surface to the precursor then to the reactant, with a purge of the chamber between each exposure, is required to form a silicon dioxide material 30 having the desired thickness as depicted in FIG. 3.

A method for forming an ALD silicon dioxide material is discussed in U.S. patent application Ser. No. 11/543,515, “Method to Deposit Conformal Low Temperature SiO₂,” filed Oct. 5, 2006. A method and structure for trench isolation is discussed in U.S. patent application Ser. No. 11/371,680, “A Method for Filling Shallow Isolation Trenches and Other Recess During the Formation of a Semiconductor Device and Electronic Systems Including the Semiconductor Device,” filed Mar. 8, 2006. These applications are assigned to Micron Technology, Inc. and are incorporated herein by reference as if set forth in their entirety.

ALD silicon dioxide exhibits good fill properties with minimal voiding and with little or no detectable seam where it impinges on itself to fill the trench, even in openings having a high aspect ratio. It further provides reasonable electrical isolation. However, ALD silicon dioxide, even when densified, is not particularly resistant to exposure to subsequent etches during normal wafer processing, for example during an etch to define flash memory device floating gates and control gates, or transistor control gates on a dynamic random access memory (DRAM) device. Moreover, any conformal SiO₂ full trench fill process may have its seam exposed in the form of a slight crevice after CMP, which may inadvertently be filled with gate material such as polysilicon, leading to short circuit effects.

The ALD silicon dioxide 30, therefore, is partially removed from the trench using an etch to result in the structure as depicted in FIG. 4. The partial removal preferably results in the upper surface of the material being at a level above the level of the tunnel oxide 12 so that the tunnel oxide 12 is not exposed to the etchant, which would degrade electrical performance. The etch itself may comprise an optional planarization process, such as a mechanical or chemical mechanical planarization (CMP), followed by a dry etch and a wet clean to remove residue. However, this process requires significant time as the wafers must be transported for CMP, then transported for the dry etch. Even omitting the CMP, the dry etch is performed one wafer at a time in a single-wafer chamber, which requires additional processing time for serial wafer etching, or requires multiple chambers for parallel wafer processing.

As such, a preferred etch process comprises the use of batch processing using a wet etch. A particularly preferred process comprises etching the silicon dioxide 30 selective to the silicon nitride 14 using a specific anhydrous hydrofluoric acid (AHF) identified in Table 1 which has been developed at Micron Technology, Inc. and referred to as “MAHF” throughout the remainder of this document.

TABLE 1
MAHF Etch Components

| Species | ppm | g/L |
|---|---|---|
| NH₄+ | 450 | 0.3547 |
| F− | 1.2 | 0.9459 |
| H₂O | 11,000 | 8.67 |
| (CHO)₄ | 500 | 0.394 |
| Isopropyl | 986,850 | 777.86 |
| Alcohol | | |

A similar etchant is discussed in a copending, commonly owned US patent publication 2006-0258169-A1 titled “Methods of etching oxide, reducing roughness, and forming capacitor construction” filed May 11, 2005 and incorporated herein by reference as if set forth in its entirety. The MAHF etchant comprises, and may consist essentially of, a mixture of ammonium fluoride NH₄F, hydrofluoric acid HF, isopropyl alcohol (CH₃)₂CHOH, maleic acid (CHO)₄, and water to result in the species concentrations listed in Table 1, (in parts per million and grams per liter), with tolerances being about ±50% for each material. To etch the SiO₂ material 30 to result in the structure of FIG. 3, the MAHF etchant is maintained at a temperature of between about 20° C. and about 40° C., and a plurality of wafers are placed into the wet etchant for a duration of between 50 minutes and about 70 minutes, for example 60 minutes, to etch 1,200 Å of exposed ALD SiO₂ such that the upper surface of the remaining ALD SiO₂ is above the level of the tunnel oxide 12 as depicted in FIG. 4.

The etch of the ALD SiO₂ material with MAHF has several advantages over other etches. For example, MAHF is selective to silicon nitride such that erosion of material 14 is minimized compared to an aggressive dry etch recess method. MAHF does not exhibit an accelerated etch of the seam which would be detrimental for the present process, and which is found with conventional wet and dry etches, for example those having a high fluorine content. Further, MAHF demonstrates a linear and uniform etch response for a 1,000 Å vertical etch with less than a 5% within-wafer variation into narrow (<50 nm) trenches.

Subsequently, the ALD SiO₂ is densified in a nitrogen environment using an anneal at about 900° C.±100° C. for a duration of about 60 minutes. Densification assists in shrinking residual ALD SiO₂ to a position lower in the trench to ensure it is not exposed to HF-based etching, for example during formation of the transistor gates and accompanying isolation. This ensures that any residual ALD SiO₂ on material 14 shrinks to a sufficient level to avoid exposure to cleans comprising a high concentration of HF during gate formation, whereas a longer MAHF recess would risk etching the tunnel oxide in some areas of the wafer. However, etching below the tunnel oxide is possible as long as any portion of the tunnel oxide (or gate oxide) which is removed is regrown. Thus, this process act would replace the N₂ densification in the flow due to the deeper recess which would likely prevent ALD SiO₂ from being exposed to cleaning chemistries. The etch rate for densified ALD oxide in MAHF on blanket wafers, which is believed to closely match the etch rate on patterned wafers, is about 23 Å/minute compared to an etch rate of about 33 Å/minute for undensified ALD oxide. The densification process is not necessary for achieving a controlled recess of ALD oxide; thus, a higher throughput MAHF etch back may be realized. Nitrogen densification is suitable for enhancing isolation properties on a flash memory device since the densification neither degrades the active area through oxidation nor negatively affects the tunnel oxide.

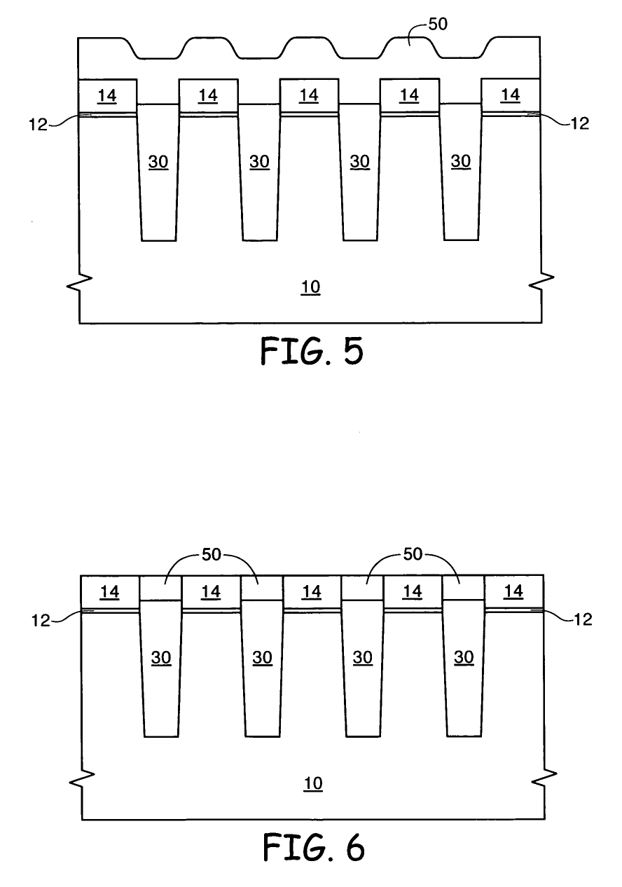

Because ALD SiO₂ is not particularly resistant to etches used in subsequent wafer processing, such as conventional etches used to form the floating gates and control gates in a flash memory device, a second fill of a more resilient isolation material may be formed over the surface of the ALD SiO₂. In this embodiment, HDP SiO₂ 50 is formed using conventional techniques to a thickness sufficient to fill the opening between each nitride portion 14 to result in the structure of FIG. 5. A thickness of about 3,500 Å would be required to fill a periphery gap (not depicted) at the array edge in addition to the array gap noted. Due to the deposition properties of the HDP SiO₂ 50, it forms to have the depicted profile. The HDP oxide 50 is then planarized, for example using CMP, to stop on the silicon nitride 14 and to result in the structure depicted in FIG. 6.

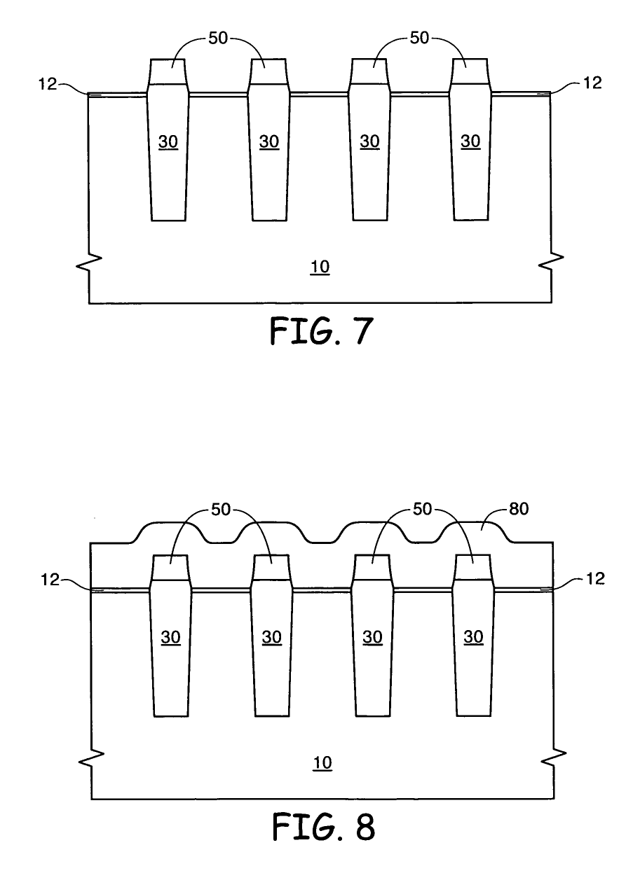

After performing CMP on the second fill material 50 of FIG. 5 to result in the FIG. 6 structure, an etch is performed to remove sacrificial material 14. In this embodiment, the etch used should remove silicon nitride selective to the HDP oxide 50, the ALD oxide 30, and the tunnel oxide 12. An etchant such as hot phosphoric acid (hot phos) would remove the silicon nitride 14 selective to the three oxide materials 50, 30, and 12 to result in the structure of FIG. 7 results, wherein the stack of HDP oxide 50 and ALD oxide 30 protrudes from the semiconductor wafer.

If an alternate process comprising a pad oxide as oxide 12 is used, the pad oxide is etched at this point to expose the wafer surface. A gate oxide is then formed to contact the wafer in accordance with techniques known in the art.

The HDP oxide demonstrates good etch resistance, for example to a 100:1 hydrofluoric acid exposure which might be used as a field clean, fluorine-based dry etches, and buffered oxide etches.

The processing times for the deposition of the ALD SiO₂ and the etch back using MAHF will be reduced as the trench widths decrease with future-generation devices; hence reducing the cost of this process flow. Depositing HDP oxide on the ALD oxide enables the use of conventional CMP and etches for later processing acts. Due to the decrease in aspect ratio provided by the partial trench fill of the ALD oxide, the HDP oxide may form as a void-free material in the remainder of the trench.

The process may continue to form damascene structures, for example transistor floating gates for a flash memory device. With this process flow, a blanket polysilicon floating gate material 80 is formed over the wafer surface as depicted in FIG. 8. To maximize the thickness of the floating gate, the upper surface of the blanket floating gate material 80 should be at a level above the upper surface of the second fill material 50. Material 80 may be formed using more than one layer, for example using a dual polysilicon process.

It is evident that the eventual thickness of the floating gate material is determined by material 50, with the thickness of material 50 being determined by the thickness of material 14. Thus the dimensions of material 14 are targeted for maximum benefit to the structure being formed.

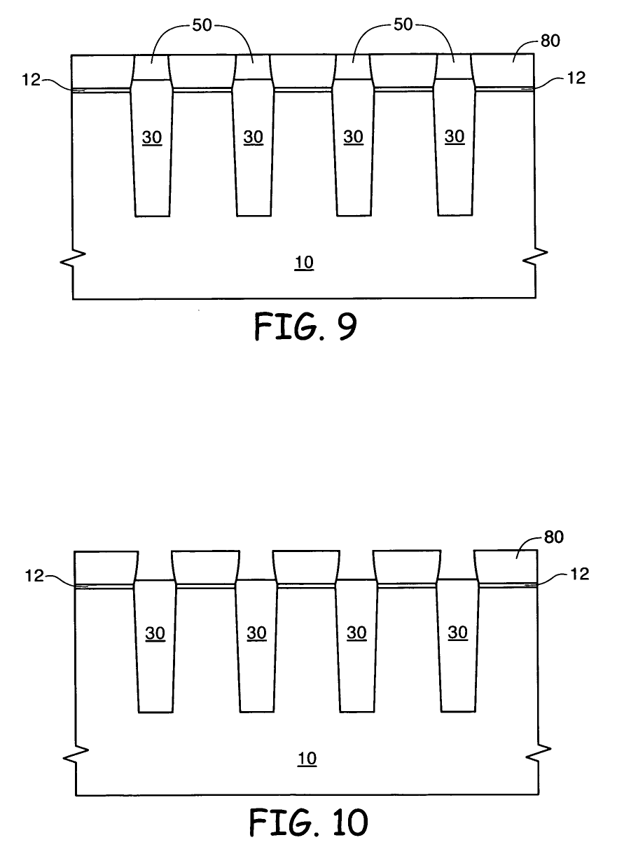

Next, the polysilicon gate material 80 as depicted in FIG. 8 is planarized, for example using CMP, to result in the structure of FIG. 9. The planarization will be typically targeted to terminate just as the HDP oxide 50 is completely exposed to maximize the thickness of the completed floating gate. Next, the HDP oxide 50 is partially etched so that it is recessed within the polysilicon features 80 as depicted in FIG. 10. The etch of material 50 is targeted so that the tunnel oxide 12 is not exposed, as damage to the tunnel oxide may result if it is exposed to the etch.

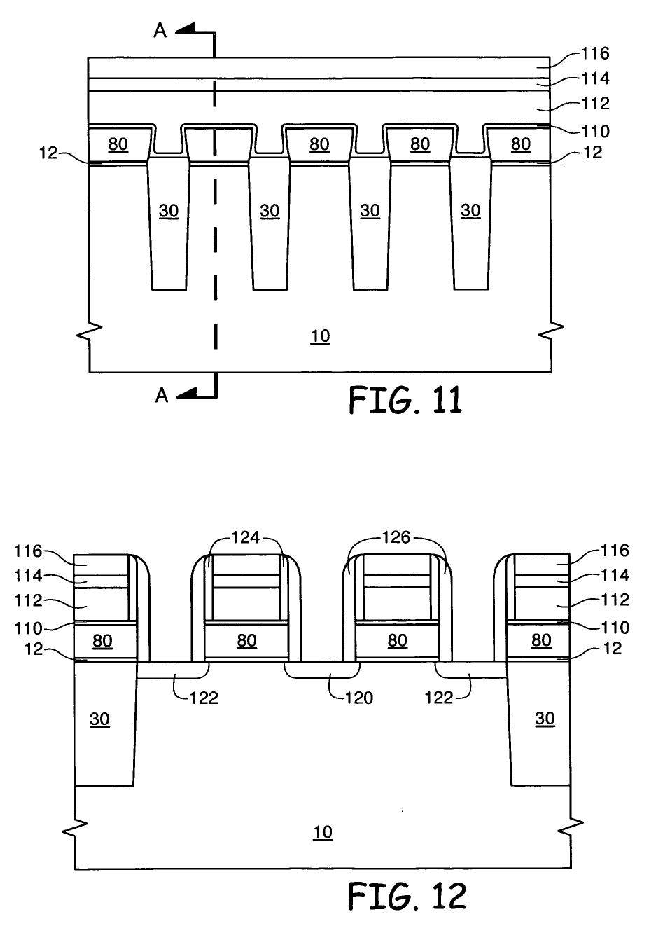

Next, an intergate dielectric 110 such as a capacitor cell dielectric formed from silicon nitride interposed between two silicon dioxide layers (i.e. an “ONO” layer, depicted for simplicity as a single layer in FIG. 11) is formed. Subsequently, a conductive material such as another polysilicon material 112 is formed, along with other materials such as a silicide 114 and a dielectric capping material 116 according to techniques known in the art. These structures provide a plurality of control gates, one of which is depicted in FIG. 11. As is known in the art, the control gate and a bit line (not depicted) used together to access the individual floating gates 80 for read and program operations. Subsequent wafer processing acts may then be performed according to techniques known in the art to form a completed semiconductor device, such as a flash memory device.

In the case of DRAM, process acts similar to those discussed relative to flash memory devices may be employed during formation of the ALD-HDP STI fill. With DRAM devices, the recess of the ALD oxide above the level above the tunnel oxide (gate oxide in the case of the DRAM) is also advantageous for sufficient electrical performance.

Various benefits also exist with regard to using the STI fill process strategies described herein during fabrication of DRAM devices which provide a competitive alternative to previous technology. In conventional devices, a polysilicon silizane spun-on dielectric (SOD) is often used as an STI fill. With this material, a TEOS liner about 75 Å may be used to reduce voiding in the SOD after densification. Similarly, an 80 Å nitride liner is used to reduce oxidation of the underlying silicon wafer during the high temperature (up to 1000° C.) steam densification of the SOD. These liners may be eliminated when the ALD-HDP oxide is used to replace the SOD oxide, although with no liner the ALD SiO₂ should remain above the level of the gate oxide after the etch back to recess the ALD SiO₂. HDP oxide provides sufficient electrical isolation on DRAM devices without densification. While the ALD SiO₂ would likely require a high temperature nitrogen densification, this type of densification would not oxidize silicon, therefore the TEOS and nitride liners may be eliminated thereby reducing manufacturing time and cost. Moreover, the disclosed fill strategy becomes increasingly attractive over conventional STI processes with future device sizes as it is anticipated that the process will scale well with decreasing trench widths and increased aspect ratios.

FIG. 12 depicts the FIG. 11 device along A-A and may include structures formed during additional processing acts. In addition to like-numbered structures of FIG. 11, FIG. 12 depicts a source region 120 and drain regions 122 implanted into the semiconductor wafer 10, first spacers 124 and second spacers 126 formed around the floating gate 80 and the control gate 112, 114. Variations to the structure of FIG. 12 and the other FIGS. are possible without departing from the scope of the invention.

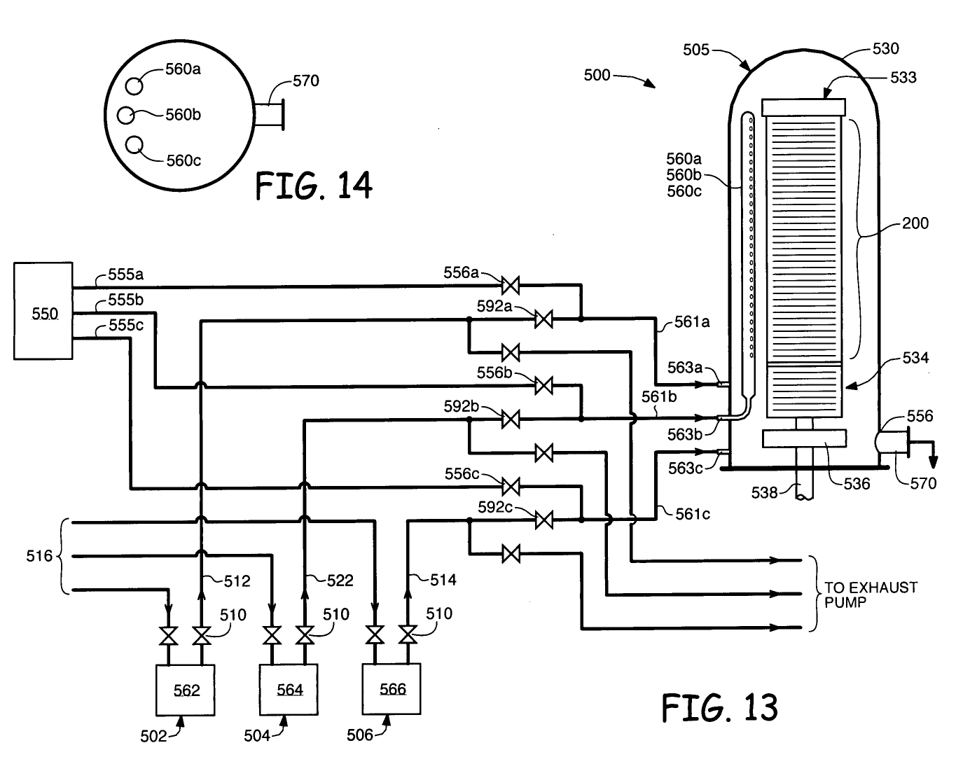

The precursor/purge/reactant/purge cycle described above for the formation of the conformal silicon dioxide can be formed in a deposition apparatus 500 such as that illustrated in FIG. 13. Such an apparatus may include a reactor chamber 505, which may be constructed entirely as a quartz container 530. Quartz container 530 may be constructed generally of glass made from high purity quartz crystal or silica sand. The bottom portion of quartz container 530 can also be constructed of a metal, such as stainless steel. Functionalized substrate wafers 200 are placed inside the reaction chamber 505 on a quartz boat 533 which can hold a plurality of substrates 200 and which is immediately adjacent to adiabatic plates 534. Pedestal 536 is adjacent to adiabatic plates 534 and quartz boat 533. Shaft 538 is connected to pedestal 536 and rotates in a counter clockwise rotation by a motor (not shown) during the ALD process. Shaft 538 causes pedestal 536 to rotate in the same direction, resulting in substrate 200 also being rotated in a counter clockwise direction. Mounted on one of the reaction chamber walls are reactive gas supply injectors 560a-c (see FIG. 14), which are further connected to reactive gas supply lines 561a-c via gas inlet ports 563a-c, each separately supplying the precursor (for example, HCD) 562, the reactant (for example, water vapor) 564, or catalyst (for example pyridine) 566 to the reaction chamber 505. Each gas supply injector 560a-c contain multiple outlet ports, or holes; which run the entire length of the gas supply injector 560a-c, providing substantially equivalent disbursement of gases within reaction chamber 505 to ensure complete and uniform coverage by the precursor, reactant, or catalyst on the plurality of substrate 200 located in reaction chamber 505. Precursor 562 is contained in first reactant ampoule 502, the reactant is contained in second ampoule 504 and the catalyst is contained in first and second catalyst ampoule 506. Purge gas (for example, nitrogen) 550 is supplied to the reaction chamber 505 through purge gas supply lines 555a-c and may be introduced into reaction chamber 505 through inlet ports 563a-c. An exhaust outlet 570, connected to a pump/exhaust system (not shown) is situated on an opposite lower wall 556 from the gas supply injectors 560a-c in reaction chamber 505. Purge gas is controlled by purge gas valves 556a-c. Precursor, reactant, and catalyst gasses are supplied to the reaction chamber 400 via chemical supply lines 512, 522, and 514 and are controlled by chemical supply line valves 592a-c.

In an alternate processing sequence, ozone TEOS or low pressure CVD (LPCVD) TEOS may be used as the bottom dielectric, with HDP oxide being deposited on the TEOS oxide. The formation of these layers is known in the art. In an embodiment of the disclosure, the dielectric used as the bottom dielectric is grown conformally with a step coverage of approximately 95% or higher. However, LPCVD TEOS typically has a much higher propensity to impinge on itself and form a visible seam than ALD SiO₂ and O₃-TEOS. In addition, ALD SiO₂ has the capability to far surpass the step coverage of these other materials, and thus would provide a superior technical advantage over successive generations of DRAM and NAND node size shrinkage.

In another alternate process, the ALD layer may be etched using a buffered oxide etch (BOE). If this etch is used, it is preferable that the anneal which densifies the ALD is performed prior to etching. Because BOE is a more aggressive etch than the MAHF (resulting from its higher fluorine content), densifying the ALD SiO₂ for between about 30 and 60 minutes in N₂ at 900° C.±100° C. will decrease the etch rate and make the etch more controllable. BOE comprises 40% ammonium fluoride concentrate (NH₄, for example through the addition of NH₄F) and 49% hydrogen fluoride (HF) concentrate. Water is added so that a water:reactant ratio is between about 500:1 to about 750:1, as this concentration preserves the seam during etching. The etch rate for densified ALD oxide in BOE on blanket wafers, which is believed to closely match the etch rate on patterned wafers, is about 34 Å/minute compared to an etch rate of about 120 Å/minute for undensified ALD oxide. When employing a BOE etch, using ALD oxide for the bottom oxide rather than LPCVD and O₃-TEOS may have inherent advantages. ALD oxide has a tight seam while the seam for LPCVD and O₃-TEOS is more exposed; thus the use of ALD oxide with the BOE etch results in a more uniform recess.

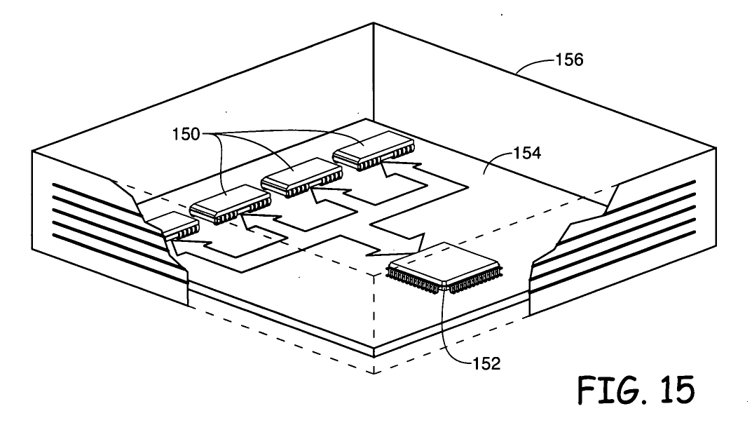

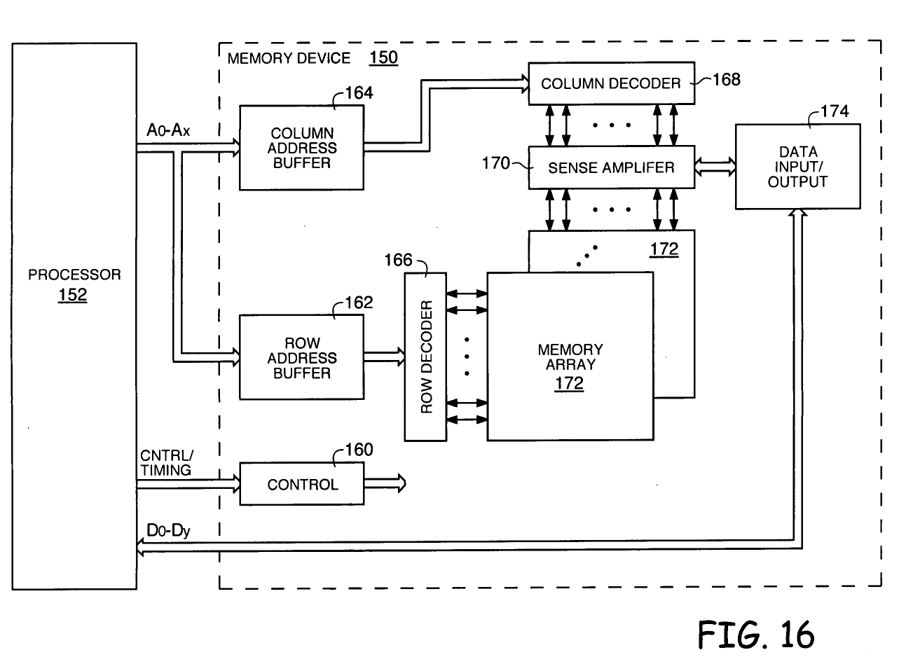

As depicted in FIG. 15, a semiconductor memory device 150 may be attached along with other devices such as a microprocessor 152 to a printed circuit board 154, for example to a computer motherboard or as a part of a memory module used in a personal computer, a minicomputer, or a mainframe 156. The microprocessor and/or memory devices may comprise an embodiment of the present invention. FIG. 15 may also represent use of device 150 in other electronic systems comprising a housing 156, for example systems comprising a microprocessor 152, related to telecommunications, the automobile industry, semiconductor test and manufacturing equipment, consumer electronics, or virtually any piece of consumer or industrial electronic equipment.

The process and structure described herein can be used to manufacture a number of different structures comprising shallow trench isolation formed according to the inventive process. FIG. 16, for example, is a simplified block diagram of a memory device such as a dynamic random access memory having dielectric isolation which may be formed using an embodiment of the present invention. The general operation of such a device is known to one skilled in the art. FIG. 16 depicts a processor 152 coupled to a memory device 150, and further depicts the following basic sections of a memory integrated circuit: control circuitry 160; row address buffer 162; column address buffer 164; row decoder 166; column decoder 168; sense amplifier 170; memory array 172; and data input/output 174.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. For example, an embodiment of the invention may be used to form isolation within openings or recesses other than the trench described herein. It is therefore contemplated that the appended claims will cover any such modifications or embodiments as fall within the true scope of the invention.

1. A method of semiconductor device fabrication, comprising:
etching a trench within a semiconductor wafer substrate assembly;
forming a first dielectric comprising atomic layer deposition (ALD) silicon dioxide within the opening;
partially etching the ALD silicon dioxide from the trench so that a first portion of the trench is filled with the ALD silicon dioxide and a second portion of the trench is unfilled with the ALD silicon dioxide; and
forming a second dielectric comprising a material different from the first dielectric within the second portion of the trench.

2. The method of claim 1 wherein the formation of the second dielectric comprises forming a high density plasma silicon dioxide.

3. The method of claim 1 wherein the formation of the second dielectric comprises forming a void-free high density plasma silicon dioxide.

4. The method of claim 1 further comprising:
densifying the ALD silicon dioxide for between about 30 and 60 minutes in a nitrogen ambient at a temperature of about 900° C.±100° C.; then
exposing the densified ALD silicon dioxide to a buffered oxide etch to partially etch the ALD silicon dioxide from the trench.

5. The method of claim 1 further comprising:
exposing the ALD silicon dioxide to MAHF to partially etch the ALD silicon dioxide from the trench; then
densifying the ALD silicon dioxide for between about 30 and 60 minutes in a nitrogen ambient at a temperature of about 900° C.±100° C.

6. The method of claim 1 further comprising etching the trench to have a width of 35 nanometers or less.

7. The method of claim 6 further comprising etching the trench to have a depth which is at least five times the width.

8. A method for forming a dielectric region for a semiconductor device, comprising:
etching a semiconductor wafer substrate assembly to have an opening therein;
forming a first dielectric within the opening using an atomic layer deposition (ALD) process such that the ALD dielectric fills a first part of the opening and leaves a second part of the opening unfilled; and
forming a second dielectric different from the first dielectric to contact the first dielectric and to fill the second part of the opening.

9. The method of claim 8 further comprising:
forming the first dielectric within the opening using the ALD process to completely fill the opening within the semiconductor wafer substrate assembly;
subjecting the first dielectric to a nitrogen ambient at a temperature of about 900° C.±100° C.; then
etching the first dielectric using a buffered oxide etch.

10. The method of claim 8 further comprising:
forming the first dielectric within the opening using the ALD process to completely fill the opening within the semiconductor wafer substrate assembly;
etching the first dielectric using MAHF; then
subjecting the first dielectric to a nitrogen ambient at a temperature of about 900° C.±100° C.

11. The method of claim 8 further comprising forming the opening in the semiconductor wafer substrate assembly to have a width of 35 nm or less.

12. The method of claim 11 further comprising forming the opening in the semiconductor wafer substrate assembly to have a depth which is at least five times the width.

13. A method of semiconductor device fabrication, comprising:
etching a trench within a semiconductor wafer substrate assembly;
forming an atomic layer deposition (ALD) dielectric within the trench using a process comprising:
exposing the etched semiconductor wafer substrate assembly to a silicon-based compound and to at least one of a heterocyclic aromatic organic compound and a Lewis base; then
exposing the etched semiconductor wafer substrate assembly to a compound containing oxygen and to at least one of a heterocyclic aromatic organic compound and a Lewis base;
etching the ALD dielectric such that the ALD dielectric fills only a first portion of the trench to a and leaves a second portion of the trench unfilled by the ALD dielectric; and
filling the second part of the trench using a dielectric different from the ALD dielectric.

14. The method of claim 13 further comprising filling the second part of the trench using high density plasma (HDP) oxide.

15. The method of claim 13 further comprising:
densifying the ALD dielectric; then
etching the ALD dielectric with a buffered oxide etch; then
filling the second part of the trench using the dielectric different from the ALD dielectric.

16. The method of claim 13 further comprising:
etching the ALD dielectric with MAHF; then
densifying the ALD dielectric; then
filling the second part of the trench using the dielectric different from the ALD dielectric.

17. The method of claim 13 further comprising flowing the silicon-based compound and the at least one of heterocyclic aromatic organic compound and Lewis base at flow rates sufficient to maintain a pressure within a deposition chamber to between about 100 mtorr and about 400 torr.

18. The method of claim 13 further comprising flowing the compound containing oxygen and hydrogen and the heterocyclic aromatic organic compound at flow rates sufficient to maintain a pressure within a deposition chamber to between about 100 mtorr and about 400 torr.

19. A semiconductor device comprising:
a trench formed within a semiconductor wafer substrate assembly;
a first dielectric which fills a majority of the trench, wherein the first dielectric comprises atomic layer deposition (ALD) oxide; and
a second dielectric different from the ALD oxide which fills a remainder of the trench.

20. The semiconductor device of claim 19 further comprising:
first and second transistor gates comprising gate or tunnel oxide, wherein the ALD oxide is subjacent and between the first and second transistor gates;
the ALD oxide being formed to a level below a level of the gate or tunnel oxide;
the second dielectric being formed at least partially directly between the first and second transistor gates.

21. The method of claim 20 further comprising:
etching a portion of the gate or tunnel oxide at a location; then
regrowing gate or tunnel oxide at the location.

22. The semiconductor device of claim 20 wherein the second dielectric comprises high density plasma oxide.

23. A method of semiconductor device fabrication, comprising:
etching a shallow isolation trench within a semiconductor wafer substrate assembly;
forming a first dielectric comprising tetraethyl orthosilicate (TEOS) within the opening using a chemical vapor deposition (CVD) process or a low-pressure CVD (LPCVD) process;
partially etching the TEOS from the trench so that a first portion of the trench is filled with the TEOS and a second portion of the trench is unfilled with the TEOS; and
forming a second dielectric comprising a material different from the first dielectric within the second portion of the trench to form shallow trench isolation within the semiconductor wafer substrate assembly.

24. The method of claim 23 wherein the formation of the second dielectric comprises forming a high density plasma silicon dioxide.
